(19) United States
(12) Patent Application Publication
(10) Pub. No.: US 2015/0282381 A1
(43) Pub. Date: Oct. 1, 2015

(54) HEAT SINK DEVICE

(71) Applicant: COMPULAB LTD., Yokneam Elite (IL)

(72) Inventor: Gideon (Genady) YAMPOLSKY, Haifa (IL)

(73) Assignee: COMPULAB LTD., Yokneam Elite (IL)

(21) Appl. No.: 14/226,835

(22) Filed: Mar. 27, 2014

(51) Int. Cl. H05K 7/20

(52) U.S. Cl. CPC H05K 7/2039

(57) ABSTRACT

A heat sink device includes a thermally conducting base plate configured to be thermally coupled to a heat source. A cover is located substantially opposite the base plate. A plurality of thermally conducting partitions extends laterally from the base plate to the cover. A lateral edge of each partition is in thermal contact with the base plate. The partitions partition a space between base plate and cover into an array of elongated channels with open opposite ends. When the base plate is thermally coupled to a heat source and the open opposite ends of a channel of the array of channels are aligned substantially vertically, a chimney effect air flow is sustained within each channel.

### FIELD OF THE INVENTION

The present invention relates to heat sink devices.

### BACKGROUND OF THE INVENTION

Electronic devices and components generate heat in the course of their operation. Joule or resistive heating, or other lossy electrical processes, may generate heat. For example, computer components that include integrated circuits may generate a significant amount of heat that could, if not removed, appreciably raise the temperature of the components and their environment.

Operation of electronic components may be adversely affected by heating. As electronic components are miniaturized, the effect of heating on operation may become magnified. Some components may not operate properly when overheated above a maximum temperature. In some components, the useful lifetime of the component may be significantly reduced by overheating.

### SUMMARY OF THE INVENTION

There is thus provided, in accordance with some embodiments of the present invention, a heat sink device including: a thermally conducting base plate configured to be thermally coupled to a heat source; a cover substantially opposite the base plate; and a plurality of thermally conducting partitions, each partition extending laterally from the base plate to the cover, a lateral edge of that partition being in thermal contact with the base plate, the partitions partitioning a space between base plate and cover into an array of elongated channels with open opposite ends, such that when the base plate is thermally coupled to a heat source and the open opposite ends of a channel of the array of channels are aligned substantially vertically, a chimney effect air flow is sustained within that channel.

Furthermore, in accordance with some embodiments of the present invention, the base plate includes a metal.

Furthermore, in accordance with some embodiments of the present invention, the metal includes copper or aluminum.

Furthermore, in accordance with some embodiments of the present invention, the base plate is substantially flat.

Furthermore, in accordance with some embodiments of the present invention, a partition of the plurality of partitions includes a metal.

Furthermore, in accordance with some embodiments of the present invention, the metal includes copper or aluminum.

Furthermore, in accordance with some embodiments of the present invention, each of the partitions is substantially flat.

Furthermore, in accordance with some embodiments of the present invention, the partitions are substantially parallel to one another.

Furthermore, in accordance with some embodiments of the present invention, the partitions extend substantially perpendicularly from the base plate.

Furthermore, in accordance with some embodiments of the present invention, the partitions and the base plate are a single unit produced by a single extrusion or casting process.

Furthermore, in accordance with some embodiments of the present invention, the cover is thermally conducting.

Furthermore, in accordance with some embodiments of the present invention, the cover is in thermal contact with a partition of the plurality of partitions.

Furthermore, in accordance with some embodiments of the present invention, an outward facing side of the cover is treated for increased emissivity.

Furthermore, in accordance with some embodiments of the present invention, the outward facing side includes black anodized aluminum.

Furthermore, in accordance with some embodiments of the present invention, an outward facing side of the cover is covered with a thermally insulating layer.

Furthermore, in accordance with some embodiments of the present invention, the cover is thermally insulating.

Furthermore, in accordance with some embodiments of the present invention, a channel of the array of channels includes a thermally conducting auxiliary fin.

Furthermore, in accordance with some embodiments of the present invention, a length of the auxiliary fin is shorter than a distance between the open ends of the channel.

Furthermore, in accordance with some embodiments of the present invention, the auxiliary fin extends from the base plate.

Furthermore, in accordance with some embodiments of the present invention, the auxiliary fin extends from the base plate along a midline between two partitions.

### BRIEF DESCRIPTION OF THE DRAWINGS

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1 is a schematic drawing of a single channel of a heat sink device, in accordance with an embodiment of the present invention.

FIG. 2 is a schematic drawing of a heat sink device with multiple channels, in accordance with an embodiment of the present invention.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, modules, units and/or circuits have not been described in detail so as not to obscure the invention.

In accordance with an embodiment of the present invention, a heat sink is configured to be thermally coupled to heat source such as an electronic component. The electronic component may include a circuit board, integrated circuit, or other electronic component that produces waste heat during its operation. The heat sink is configured to efficiently transfer heat from the electronic element to the ambient atmosphere without the use of fans, blowers, or other devices that force convection of air past the heat sink. The heat sink includes one or a plurality of channels within which chimney effect air flow may be initiated and sustained to provide effective heat transfer from the heat source to the ambient atmosphere.

As used herein, thermal coupling refers facilitating conductive, convective, or radiative heat transfer between the thermally coupled or connected elements. Thermal contact, as used herein, refers to facilitating or enabling heat conduction.

A heat sink device, in accordance with an embodiment of the present invention, includes a thermally conducting base plate and a cover substantially opposite (e.g., at a fixed distance from and at least locally parallel to) the base plate. The base plate and cover partially enclose a space between them. Two opposite ends of the enclosed space are open. A plurality of thermally conducting partitions extends longitudinally from one of the open ends to the opposite open end. A proximal lateral edge of each partition is in thermal contact with the base plate. The other, distal, lateral edge of each partition extends to the cover (or may be bent to form the cover). Each partition thus extends laterally from the base plate to the cover. The partitions partition the space between the base plate and cover into a plurality elongated channels, each channel being laterally enclosed and open at (longitudinally) opposite ends.

As used herein, a longitudinal axis of a channel, or a longitudinal direction, refers to an axis or direction that is parallel (or substantially parallel) to a line that extends from the middle (e.g., geometrical center) of one of the end openings of the channel to the middle of the opposite end opening. A lateral side of the channel or of the device, or a lateral edge of a partition, refers herein to a side in a plane that is substantially parallel to the longitudinal axis.

A heat sink device, in accordance with an embodiment of the present invention, is thus divided into one or a plurality of enclosed elongated channels whose ends are open to the ambient atmosphere. The ambient atmosphere may include air, or may include a specialized gaseous atmosphere, e.g., sustained within a container within which the heat sink is enclosed or sealed. For the sake of simplicity and clarity, components of any such atmosphere are herein referred to as air. When in operation, air may flow from one end of the heat sink channel to the other, thus facilitating heat transfer to the air. The flow of air may be initiated or sustained by the chimney effect, as described below.

When the ends of the heat sink channel are oriented sufficiently close to the vertical (e.g., the longitudinal axis of the channel being substantially vertical, or forming an oblique angle with the vertical), air flow through the heat sink channel is driven by the chimney (or stack) effect. A degree of verticality (e.g., maximum angular deviation of the longitudinal axis from the local vertical) that is required to enable chimney-effect-driven air flow in a channel may depend on such factors as temperature or heat generation rate (power) of the heat source, atmospheric conditions (composition, temperature, humidity, ambient pressure, speed and direction of wind or ambient air flow), dimensions of the channel (e.g., ratio of opening size to length), or other factors.

When air flow is driven by the chimney effect, air in the heat sink channel is heated by heat from the electronic component. For example, the electronic component may be thermally coupled to a lower portion (e.g., bottom third) of each heat sink channel. As the air is heated, the air increases in buoyancy and rises toward the outflow opening at the upper end of the heat sink channel. The rising of the heated air causes cooler air to be drawn into the through intake opening at the lower end of the heat sink channel. The air that is drawn in is heated in turn, rising and thus sustaining the air flow through the heat sink channel. The air flow may begin spontaneously when the heat sink channel when the heat source begins to generate heat. The air flow may be self-sustaining as long as the heat source generates heat. The sustained air flow through the channel may enhance the effectiveness of heat removal from the electronic component by the channel. Thus, forced convection using an externally powered fan or blower may not be required to remove heat from the heat source.

A heat sink array includes an enclosed structure that is partitioned into a plurality of substantially parallel heat sink channels. Channels of the heat sink array may be thermally coupled to the heat source. A common base plate (e.g., planar or curved) of the array may be positioned or mounted to thermally couple the heat sink array to the heat source. Typically, when the heat sink is in operation, the heat source is thermally coupled to a lower section of the heat sink array. For example, the heat source may be coupled to the lowermost third of the length of each heat sink channel.

Each channel includes a thermally conducting elongated base plate that may be thermally coupled to the electronic component or other heat source. For example, the base plate may be made of or include a thermally conductive material (e.g., a metal such as copper or aluminum, or another thermally conducting material), or may be provided with heat-conducting structure (e.g., one or more heat pipes or vapor chambers). The thermal coupling of the base plate to the heat source may be direct. Alternatively or in addition, the thermal coupling may be indirect. An indirect thermal coupling may include an intervening heat conducting element that is thermally coupled to both the heat source and the base plate. An array of channels of a heat sink may share a common base plate.

Two substantially opposite (e.g., parallel or having parallel axes) lateral sides of each channel are closed by thermally conducting side partitions that extend from the base plate. For example, the side partitions may be constructed of a thermally conducting material (e.g., metal, such as copper or aluminum, or another thermally conducting metal or material), or may include heat pipes or other thermally conducting elements or structure. A proximal edge of each of the side partitions is attached and in thermal contact with the base plate. The side partitions may extend substantially perpendicularly from base plate, or may extend from the base plate at an oblique angle. A side partition may have a bent or curved cross section. A thickness of the side partition may be selected to facilitate heat transfer from the base plate to air within the channel. For example, a side partition may be sufficiently thin so as not to impede air flow and so as to increase the surface-to-volume ratio of the side partition. On the other hand, the side partition may be sufficiently thick so as to enable efficient heat conduction within the side partition from the base plate to the distal edge of the side partition (e.g., preventing formation of appreciable heat gradients within the side partition). When the channel is part of an array of adjacent channels, two adjacent channels of the array may share a single common side partition.

An elongated cover covers the distal edges of the side partitions and encloses the distal side of the channel. The cover may be thermally conducting or thermally insulating. A thermally conducting cover may be in thermal contact with the side partitions. A thermally conducting cover may thus serve to further transfer heat from the side partitions to air within the channel and outside the channel. On the other hand, a thermally insulating cover may prevent contact of heated surfaces with human skin or heat-sensitive objects or materials. An array of channels of a heat sink may share a common cover. In some cases, the cover of an individual channel may be vanishingly small (e.g., having a triangular cross section) or may form a single wall with one or both side partitions (e.g., an arced or curved cross section).

Thus, the base plate, side partitions, and cover enclose an elongated channel. The ends of the channel are open to enable air or another gas, or other fluid, to flow in a direction that is substantially parallel to the longitudinal axis of the channel. The cross section of the channel may be rectangular (e.g., if substantially straight side partitions extend substantially perpendicularly from the base plate), parallelogram (e.g., if substantially straight side partitions extend in parallel at a constant oblique angle from the base plate), trapezoidal (e.g., if substantially straight side partitions extend at different or alternating opposite oblique angles from the base plate), polygonal (e.g., if the side partitions have cross sections in the form of straight segments connected at bends), or another shape. Adjacent channels of an array may have alternating complementary shapes (e.g., alternately inverted trapezoids or triangles, or alternating convex and concave polygons or other shapes).

A channel may include one or a plurality of additional conducting fins. One or more auxiliary fins may extend from the base plate, side partitions, or (conducting) cover into the channel. An auxiliary fin typically extends along part of the length of the channel. Edges and profiles of the auxiliary fins may be configured aerodynamically (e.g., thin with appropriately curved edges) so as not to interfere with, air flow within the channel. The auxiliary fins may be located within the channel so as to enhance heat transfer from the fin to the air in the channel. For example, an auxiliary fin may extend from the base plate along a midline between two side partitions of the channel. The auxiliary fin may be located in a section of the channel that is nearest to the heat source. For example, the auxiliary fin may be located in a lower third of the channel, when in operation. The auxiliary fin may increase a rate of heat transfer from the electronic component to the air that flows within the channel.

In some embodiments of the present invention, various components of the channel may be formed in a single extrusion or molding process. For example, two or more of a base plate, side partitions, and cover may be extruded in a single step from a metal extruder. A base plate, side partitions, and auxiliary fins may be formed in a single molding process. Similarly, an array of adjacent channels or of channel components may be formed by a single extrusion or molding process.

A heat sink in accordance with embodiments of the present invention may be advantageous over conventional heat sinks for electronic components. Conventional heat sinks typically include an array of fins that are exposed to the ambient atmosphere. For comparable size and performance, a typical conventional heat sink would require forced convection (e.g., by a fan) to enable efficient removal of heat from the electronic component.

In accordance with an embodiment of the present invention, simulation tools or computer programs may be applied to a design of a sink. Application of the simulation tool may indicate an expected effectiveness of a particular design in removing heat from an electronic component or other heat source. Various design parameters may be varied to find a design that is suitable to remove heat under particular circumstances. Particular circumstances may include, for example, a type of electronic component or other heat source, a type of thermal coupling between the heat source and the heat sink, environmental conditions (e.g., an expected range of ambient temperature, humidity, and air pressure, or other atmospheric conditions; presence of other heat generating components, or of other housings or structures), use cycle, placement (e.g., control over orientation or tilt), or other circumstances. Design parameters that may be varied may include channel shape, channel dimensions, relative proportions and dimensions of components of the channels, materials incorporated in the channels, or other design parameters or considerations.

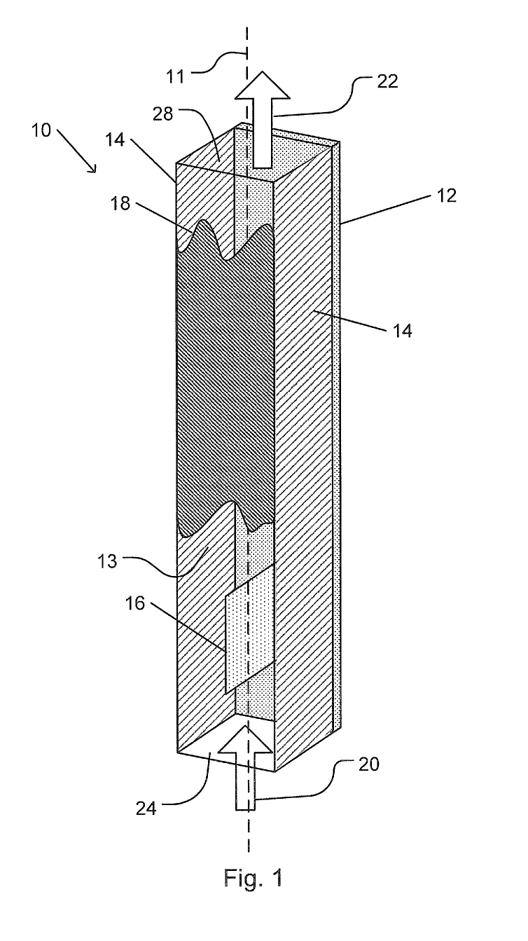

FIG. 1 is a schematic drawing of a single channel of a heat sink device, in accordance with an embodiment of the present invention.

Heat sink channel 10 is configured to be thermally coupled to a heat source from which heat is to be removed and dissipated. When heat sink channel 10 is in operation, longitudinal axis 11 of heat sink channel 10 is substantially vertical. In some cases, longitudinal axis 11 may be oriented at an oblique angle to the vertical. For example, in some cases, efficient or effective operation of heat sink channel 10 may require that longitudinal axis 11 not be tilted by more than 45° from with respect to the vertical. In other cases (e.g., depending on absolute or relative dimensions of components of heat sink channel 10), heat sink channel 10 may operate effectively or efficiently when longitudinal axis 11 is tilted at another oblique angle.

When heat sink channel 10 is in operation or in use, intake opening 24 is positioned below outflow opening 26. In some cases, intake opening 24 and outflow opening 26 are interchangeable. For example, the structure of heat sink channel 10 may be substantially symmetric about a plane that bisects heat channel 10 along longitudinal axis 11. As another example, heat sink channel 10 may function in substantially the same manner when inverted top-to-bottom.

Base plate 12 of heat sink channel 10 is configured for thermal coupling with a heat source, such as an electronic component. Base plate 12 is configured, when thermally coupled to the heat source, to conduct heat from the heat source to interior space 13 of heat sink channel 10. For example, base plate 12 may include a thermally conducting material. A thermally conducting material may include, for example, a metal (e.g., aluminum or copper), or another thermally conducting material. The thickness of conducting material in base plate 12 may be sufficient to enable lateral distribution of heat over interior space 13 and to side partitions 14 while effectively transferring heat from the heat source to interior space 13. Alternatively or in addition, base plate 12 may enclose (e.g., by an enclosure with at least some thermally conducting sides or surfaces) heat conducting structure. Heat conducting structure may include, for example, one or more heat pipes, vapor chambers, or other heat conducting structure.

The heat source may include, for example, an electronic component or other device that generates heat and from which heat is to be removed. The heat source may include a heat conducting structure that conveys heat from a heat generating device to base plate 12. Thermal coupling between base plate 12 and the heat source may be mechanical (e.g., physical contact, possible augmented or facilitated by mechanical clamping), may include chemical bonding (e.g., via a thermally conducting epoxy or other adhesive), may be radiative (e.g., where a surface of base plate 12 that faces the heat source is blackened or otherwise treated to effectively absorb thermal radiation), or may be convective over a gap between base plate 12 and the heat.

In some cases, substantially all of base plate 12 is thermally coupled to the heat source. In some cases, only part of base plate 12 is thermally coupled to the heat source. For example, only a lower part of base plate 12 may be thermally coupled to the heat source.

Base plate 12 may be flat, as shown. In some cases, a base plate may be curved. For example, curving of a base plate may facilitate thermal coupling between the curved base plate and a cylindrical or spherical heat source. When the base plate is curved, other components of the heat sink channel may be curved (e.g., side partitions or channel covers) or be angled (e.g., side partitions) to accommodate the curvature.

Side partitions 14 of heat sink channel 10 are in the form of thermally conducting fins. For example, side partitions 14 may be made of, or may include, a metal or other thermally conducting material. The proximal edges of side partitions 14 are attached and in (conductive) thermal contact with base plate 12. For example, side partitions 14 and base plate 12 may be made of a single material. When made of a single material, side partitions 14 and base plate 12 may be produced by a single extrusion or casting process.

Side partitions 14 may extend substantially perpendicularly outward from base plate 12, as shown. Alternatively or in addition, one or more side partitions 14 may extend outward at an oblique angle from base plate 12.

Side partitions 14 may be substantially flat (e.g., with a straight cross section) as shown. Alternatively or in addition, one or more side partitions 14 may include straight elongated sections whose edges meet at corners or bends (e.g., at obtuse angles), may have a curved cross section, or may include one or more elongated sections having curved cross sections.

Dimensions of side partitions 14 may be selected to facilitate heat transfer from base plate 12 to air that is in interior space 13 of heat sink channel 10. For example, side partitions 14 may be made sufficiently thin so as not to interfere with (e.g., reduce the volume of) air flow through heat sink channel 10, or through an array of heat sink channels 10. Thinness of side partitions 14 may facilitate (e.g., by resulting in a high surface-to-volume ratio for side partitions 14) heat transfer from side partitions 14 to an air flow in interior space 13. On the other hand, side partitions 14 should be sufficiently thick to enable efficient heat conduction from base plate 12 to the distal edges of side partitions 14 (e.g., such that an appreciably large temperature gradient is not formed within side partition 14). Edges of side partitions 14 (e.g., at intake opening 24, at outflow opening 26, or both) may be aerodynamically shaped (e.g., appropriately curved or otherwise shaped) to facilitate air flow at the edges.

Dimensions of interior space 13 (e.g., defined by a width of each side partition 14 and a separation between side partitions 14) of a heat sink channel 10 may be configured to promote or optimize chimney effect flow of air within interior space 13. For example, lateral dimensions of interior space 13 may be selected to balance requirements of minimal resistance to longitudinal air flow, on the one hand, and efficient transfer of heat to the enclosed air on the other.

For example, in some cases a length of heat sink channel 10 may be limited to about 26 cm (e.g., in a mini-tower computer case). Lateral dimensions of an interior space 13 with a square cross section may be about 15 mm×15 mm (e.g., for use with a 100 W heat source). On the other hand, when each lateral dimensions is about 30 mm or more, or about 15 mm or less, chimney effect air flow may not be initiated or sustained. In some cases, an optimal dimension of interior channel 13 increase or decrease by a factor proportional to the square root of the increase or decrease of the length of heat sink channel 10. (For example, when the length of heat sink channel 10 is about 52 cm, an optimal lateral dimension of interior space 13 may be about 21 mm).

Heat sink channel 10 may include one or a plurality of auxiliary fins 16. For example, an auxiliary fin 16 may extend from base plate 12 into interior space 13 of heat sink channel 10 along a midline between side partitions 14. Two or more auxiliary fins 16 may extend from base plate 12 at other positions on base plate 12.

Auxiliary fin 16 is made of, or includes, a conducting material. For example, auxiliary fin 16 may be made of, or may include, a metal or other thermally conducting material. The proximal edge of auxiliary fin 16 is attached and in thermal contact with base plate 12.

An auxiliary fin 16 may be shorter than heat sink channel 10. The shorter length may inhibit or prevent formation of a thick thermal boundary layer that could interfere with air flow through interior space 13. A length of auxiliary fin 16, or a lateral dimension (e.g., width or thickness) of auxiliary fin 16, may be selected in consideration of dimensions of heat sink channel 10 and an expected working temperature or conditions. For example, dimensions of auxiliary fin 16 may be selected so as not to interfere with chimney effect air flow (e.g., by increasing drag or other airflow resistance forces), on the one hand, and by effectively increasing heat transfer to the enclosed air on the other.

Auxiliary fin 16 may be positioned within heat sink channel 10 at what is expected to be a hottest point on base plate 12 (e.g., closest to the heat source). Two or more auxiliary fins 16 may extend from laterally displaced positions at a single longitudinal position along a lateral axis of base plate 12.

Alternatively or in addition, auxiliary fins may extend into interior space 13 from one or more side partitions 14 (if compatible with the aforementioned limitations regarding promoting heat transfer while not excessively interfering with chimney effect air flow within interior space 13).

Auxiliary fin 16 may be formed together with one or more of base plate 12 or side partitions 14 in a single casting process. Alternatively or in addition, an auxiliary fin 16 may be formed separately and attached (e.g., welded or connected using a thermally conducting epoxy or other adhesive) to base plate 12 or to a side partition 14.

Auxiliary fin 16 may extend substantially perpendicularly outward from base plate 12, as shown. Alternatively or in addition, one or more auxiliary fins 16 may extend outward at an oblique angle from base plate 12 (or from a side partition 14).

Auxiliary fin 16 may be flat, as shown. Alternatively or in addition, one or more auxiliary fins may have a bent or curved cross section. One or more edges or ends of auxiliary fin 16 may be aerodynamically shaped (e.g., curved). An aerodynamic shape may reduce interference with air flow in interior space 13, or may direct the flow to increase effectiveness of heat transfer within heat sink channel 10.

Channel cover 18 attaches to, or covers, the distal edges of side partitions 14. (Only a section of channel cover 18 is shown, to enable illustration of interior structure of heat sink channel 10.) When covering the distal edges of side partitions 14, channel cover 18 encloses all sides of interior space 13 (except for intake opening 24 and outflow opening 26 at the ends of heat sink channel 10). Channel cover 18 may thus direct the flow of air within interior space 13 and prevent outward (distal) dissipation of the air flow. When so enclosed, the chimney effect may initiate and sustain an air flow within interior space 13.

In some cases, channel cover 18 may be made of, or include, a conducting material. For example, channel cover 18 may be made of, or may include, a metal or other thermally conducting material. When channel cover 18 is thermally conducting, channel cover 18 may be in thermal contact with one or both of side partitions 14. The thermal contact may thus enable conduction of heat from side partitions 14 to channel cover 18. The area of the heat conducting surfaces is thus increased, facilitating heat transfer to an air flow within interior space 13. When channel cover 18 is made of the same material as side partitions 14, channel cover 18 and side partitions 14 (and, possibly, base plate 12) may be produced by a single extrusion or casting process.

A thermally conducting channel cover 18 may, in addition, facilitate dissipation of heat from the heat source by transferring heat to the ambient environment outside of heat sink channel 10. For example, contact with ambient air outside of heat sink channel 10 may enable additional passive convective cooling of heat sink channel 10. Alternatively or in addition, a thermally conducting channel cover 18 may be configured to dissipate heat by thermal radiation. An outward facing surface of channel cover 18 may be treated to increase its emissivity of thermal radiation. For example, an outward facing surface of an aluminum channel cover 18 may be anodized to form black anodized aluminum.

In some cases, channel cover 18 may be thermally insulating. Alternatively or in addition, an exposed outward-facing surface of channel cover 18 may be thermally insulated (e.g., coated or covered with a thermally insulating layer). For example, it may be desirable to limit the temperature of the outward-facing surface where the outward-facing surface may come in contact with human (or animal) skin, with inflammable or heat sensitive materials or objects, or in other circumstances where heating of an exposed surface is preferably avoided.

Heat sink channel 10 may operate to transfer heat from a heat source via base plate 12 to air flowing through interior space 13 of heat sink channel 10. When in operation, base plate 12 is (directly or indirectly) thermally coupled to the heat source. Heat sink channel 10 is oriented such that longitudinal axis 11 is close to vertical (e.g., within 45° of vertical). When so oriented, intake opening 24 is at the lowermost point of heat sink channel 10, and outflow opening 26 is at the uppermost point.

Under these conditions, cool air may enter interior space 13 via intake opening 24, as indicated by intake flow 20. The cool air of intake flow 20 may be heated within interior space 13. For example, heat that is conducted from the heat source via one or more of base plate 12, side partitions 14, auxiliary fin 16, and (a conducting) channel cover 18, may contact and warm the air within interior space 13. When the air is heated, the heated air becomes more buoyant than inflowing cool air. The sides (base plate 12, side partitions 14, and channel cover 18) constrain motion of the heated air by preventing outward flow. Thus, the constrained heated buoyant air flows upward within interior space 13. During the upward flow, more heat may be transferred to the flowing air, further increasing the air's buoyancy and further increasing the upward interior flow. When the upwardly flowing heated air reaches outflow opening 26, the heated air flows upwardly outward, as indicated by outflow 22. Outflow 22 carries the heated air upward into the ambient atmosphere where the heat may be dissipated. Due to the upward direction of outflow 22, ambient atmospheric pressure forces cool air to enter intake opening 24, where it is heated. Thus, the chimney effect may initiate and maintain a steady flow of upward flow of air through interior space 13. Heat may thus be transferred from the heat source to air in the ambient atmosphere.

In some cases, a single heat sink channel 10 may be used to transfer heat from the heat source to the ambient atmosphere. In other cases, a heat sink channel 10 may be part of a heat sink array of a heat sink device. A heat sink array may include an enclosed space that is partitioned into a plurality of channels, e.g., each similar in structure to heat sink channel 10 or a variation thereof. Various partitioned channels of the array may be separated from one another by spaces, or may be adjacent to one another. For example, in a heat sink array, conducting partitions may function as a common wall (e.g., functionally similar to side partition 14) of two adjacent partitioned channels. Partitioned channels of a heat sink array may share a common base plate (e.g., similar in function to base plate 12 and large enough to form a conducting base for all of the partitioned channels), a common cover (e.g., functionally similar to channel cover 18 and large enough to cover all of the partitioned channels), or both.

Adjacent partitioned channels of a heat sink array may have identically shaped cross sections (e.g. channels with identical rectangular cross sections on a substantially flat common base plate, or channels with identical trapezoidal cross sections on a convex or concave common base plate), may have complementary shapes (e.g., channels with alternating inverted trapezoidal cross sections on a flat common base plate, or channels with alternating convex and concave side partitions), or may have different shapes (e.g., cross sections configured to an expected temperature distribution across a common base plate, configured to accommodate expected spatial variations in ambient conditions as in an enclosed space, or otherwise varied).

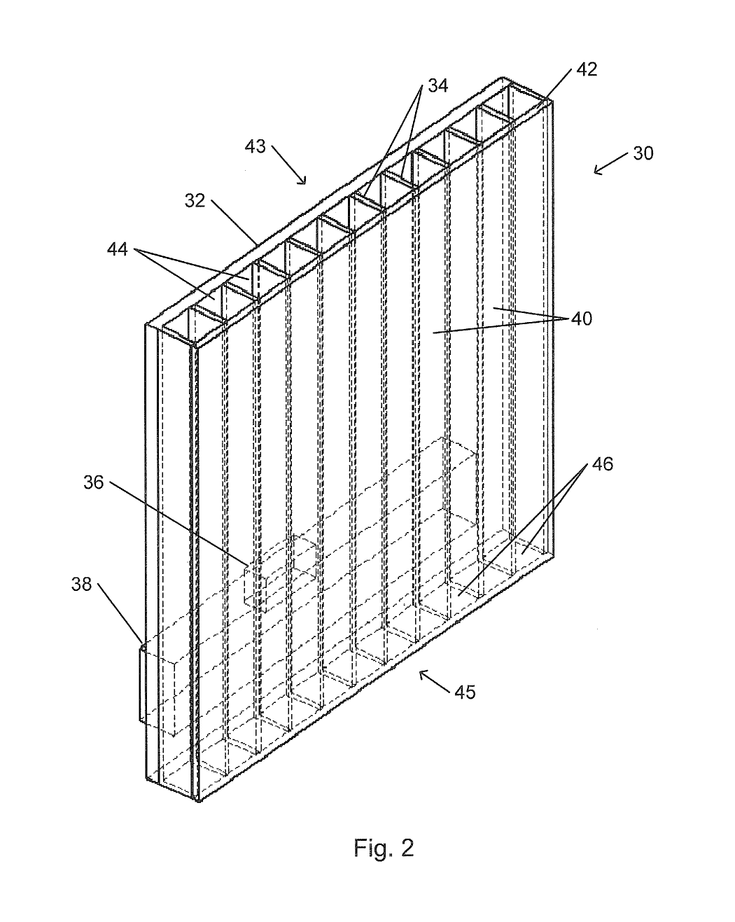

FIG. 2 is a schematic drawing of a heat sink device with multiple channels, in accordance with an embodiment of the present invention.

Heat sink device 30 is configured to dissipate heat that is generated by heat source 36. For example, heat source 36 may include an electronic component, such as a circuit board, integrated circuit, or other electronic component that generates waste heat.

Heat sink device 30 is partitioned by thermally conducting partitions 34 into partitioned channels 40. Similarly, thermally conducting partitions 34 partition array opening 43 into channel outflow openings 44, and array opening 45 into channel intake openings 46. (In some cases, the designation of channel openings as intake and outflow openings may depend on an orientation of heat sink device 30 when in operation. For example, inverting heat sink device 30 from top to bottom may change the function of an intake opening to an outflow opening, and vice versa. When partitioned channels 40 include auxiliary fins, operation of heat sink device 30 may require that heat sink device 30 be oriented such as the auxiliary fins are in the lower part, such as the lowermost third, of heat sink device 30.)

All partitioned channels 40 of heat sink device 30 share a common base plate 32. Common base plate 32 is configured to transfer heat from heat source 36 to air that is in interior spaces of partitioned channels 40. For example, common base plate 32 may include a thermally conducting material, such as a metal (e.g., aluminum or copper), or other thermally conducting material. The thickness of conducting material in common base plate 32 may be sufficient to enable lateral distribution of heat over all or some of partitioned channels 34 while effectively transferring heat from heat source 36 to partitioned channels 34. Alternatively or in addition, common base plate 32 may enclose or include heat conducting structure. Heat conducting structure may include, for example, one or more heat pipes, vapor chambers, or other heat conducting elements or structure.

In the example shown in FIG. 2, the area of heat source 36 that faces common base plate 32 is much smaller than that of common base plate 32. Common base plate 32 is, therefore, thermally coupled to heat source 36 via heat conducting element 38. Heat conducting element 38 is configured to increase the area of a region of common base plate 32 over which heat from heat source 36 distributed (e.g., relative to a size of the region over which heat would be distributed by direct thermal coupling to heat source 36). For example, heat conducting element 38 may include a thermally conducting mass, heat pipes, vapor chambers, conducting elements or fluids, or other structure or elements that enable conduction of heat and increasing a size of a region over which heat is distributed. Operation of (chimney effect flow within) heat source 36 may require that heat source 36 or heat conducting element 38 be thermally coupled to a lower portion (e.g., lowermost third) of each partitioned channel 40 of heat sink device 30.

Each pair of adjacent partitioned channels 40 of heat sink device 30 is separated by a common thermally conducting partition 34. Thermally conducting partitions 34 are in thermal contact with common base plate 32. The common thermally conducting partition 34 acts as a side partition of each of the two adjacent partitioned channels 40. Partitioned channels 40 may function to facilitate conduction of heat from common base plate 32 to the interior of partitioned channels 40.

All partitioned channels 40 of heat sink device 30 are covered by a common array cover 42. Common array cover 42 may be attached or bonded to some or all of thermally conducting partitions 34. Alternatively or in addition, some or all partitions of a heat sink array may be bent or curved so as to enclose all lateral sides of those partitioned channels.

In some cases, common array cover 42 may be made of, or include, a conducting material, such as a metal or other thermally conducting material. When common array cover 42 is thermally conducting, common array cover 42 may be in thermal contact with one or both of thermally conducting partitions 34. The area of the heat conducting surfaces is thus increased, facilitating heat transfer to air flow within partitioned channels 40.

A thermally conducting common array cover 42 may facilitate dissipation of heat from heat source 36 by transferring heat to the ambient environment outside of heat sink device 30. For example, contact with ambient air outside of heat sink device 30 may enable additional passive convective cooling of heat sink device 30. Alternatively or in addition, a thermally conducting common array cover 42 may be configured to dissipate heat by thermal radiation. An outward facing surface of common array cover 42 may be treated to increase its emissivity of thermal radiation. For example, an outward facing surface of array cover 42 may include black anodized aluminum.

In some cases, common array cover 42 may be thermally insulating. Alternatively or in addition, an exposed outward-facing surface of common array cover 42 may be thermally insulated. Insulation of common array cover 42 may limit the temperature of the outward-facing surface where the outward-facing surface may come in contact with human skin or with inflammable or heat sensitive materials or objects, or in other circumstances where heating of an exposed surface is to be avoided.

Some or all of heat sink channels 40 may include one or more auxiliary fins (not shown).

When heat sink device 30 is in operation, heat from heat source 36 is conducted to common base plate 32 via heat conducting element 38. Heat sink device 30 is oriented such that heating of common base plate 32 and of thermally conducting partitions 34 heats air enclosed within each of partitioned channels 40. When heated, the air enclosed in each partitioned channel 40 rises toward channel outflow opening 44 of that partitioned channel 40. The outflow of heated air from channel outflow opening 44 causes cool air to flow into channel intake opening 46 of that partitioned channel 40. The outflow of heated air and the intake of cooler air may initiate and sustain a chimney effect flow of air through some or all of partitioned channels 40. For example, operation of a chimney effect in one of partitioned channels 40 may depend on the fraction of heat from heat source 36 that is conducted to that partitioned channel 40.

Some or all components of heat sink device 30 may be formed by a single process. For example, common base plate 32 and partitions 34 may be formed by a single extrusion or casting process. Common base plate 32, shared side partitions 34, and common channel cover 42, may be formed by a single extrusion process.

1. A heat sink device comprising:
a thermally conducting base plate configured to be thermally coupled to a heat source;
a cover substantially opposite the base plate; and
a plurality of thermally conducting partitions, each partition extending laterally from the base plate to the cover, a lateral edge of that partition being in thermal contact with the base plate, the partitions partitioning a space between base plate and cover into an array of elongated channels with open opposite ends, such that when the base plate is thermally coupled to a heat source and the open opposite ends of a channel of the array of channels are aligned substantially vertically, a chimney effect air flow is sustained within that channel.

2. The device of claim 1, wherein the base plate comprises a metal.

3. The device of claim 2, wherein the metal comprises copper or aluminum.

4. The device of claim 1, wherein the base plate is substantially flat.

5. The device of claim 1, wherein a partition of the plurality of partitions comprises a metal.

6. The device of claim 5, wherein the metal comprises copper or aluminum.

7. The device of claim 1, wherein each of the partitions is substantially flat.

8. The device of claim 7, wherein the partitions are substantially parallel to one another.

9. The device of claim 7, wherein the partitions extend substantially perpendicularly from the base plate.

10. The device of claim 1, wherein the partitions and the base plate are a single unit produced by a single extrusion or casting process.

11. The device of claim 1, wherein the cover is thermally conducting.

12. The device of claim 11, wherein the cover is in thermal contact with a partition of the plurality of partitions.

13. The device of claim 11, wherein an outward facing side of the cover is treated for increased emissivity.

14. The device of claim 13, wherein the outward facing side comprises black anodized aluminum.

15. The device of claim 11, wherein an outward facing side of the cover is covered with a thermally insulating layer.

16. The device of claim 1, wherein the cover is thermally insulating.

17. The device of claim 1, wherein a channel of the array of channels comprises a thermally conducting auxiliary fin.

18. The device of claim 17, wherein a length of the auxiliary fin is shorter than a distance between the open ends of the channel.

19. The device of claim 17, wherein the auxiliary fin extends from the base plate.

20. The device of claim 19, wherein the auxiliary fin extends from the base plate along a midline between two partitions.
